(19) United States
(12) Patent Application Publication
(10) Pub. No.: US 2021/0058082 A1
(43) Pub. Date: Feb. 25, 2021

(54) Low Power Consumption Selector

(71) Applicant: Shanghai Huali Microelectronics Corporation, Shanghai (CN)

(72) Inventors: Weihuan Gao, Shanghai (CN); Xiaoming Hu, Shanghai (CN)

(73) Assignee: Shanghai Huali Microelectronics Corporation, Shanghai (CN)

(21) Appl. No.: 16/686,526

(22) Filed: Nov. 18, 2019

(30) Foreign Application Priority Data
Aug. 19, 2019 (CN) 201910762859.9

(51) Int. Cl. H03K 17/687

(52) U.S. Cl. CPC H03K 17/6872; H03K 2217/0036

(57) ABSTRACT

The invention provides a low power consumption selector the first PMOS's source is connected with a first data signal; the first PMOS's gate is connected with a data selection signal; the first NMOS's source is connected with a second data signal; the first NMOS's gate is connected with the data selection signal; the first NMOS's drain and the first PMOS's drain are connected and as output, access an input of the buffer; the buffer's output is used as the selector's output. When the selection signal is high level, an input signal of the buffer is the second data signal; and when the selection signal is low level, the input signal of the buffer is the first data signal. Finally, the input signal is transmitted to the output signal through the buffer. The low-power selector only needs three PMOSs and three NMOSs, which greatly reduces the power loss.

### CROSS REFERENCE TO RELATED APPLICATIONS

The present application claims priority to Chinese Patent Application No. 201910762859.9 filed on Aug. 19, 2019, the disclosure of which is incorporated herein by reference in its entirety as part of the present application.

### BACKGROUND

The invention relates to the field of circuit design, in particular to a low power consumption selector.

A conventional selector, as shown in FIG. 1, includes a first phase inverter, a first data transmission circuit, a second data transmission circuit and a second phase inverter. After the first phase inverter carries out negation on a selection signal S, an S negation signal is formed and accesses a PMOS transistor of the first data transmission circuit and an NMOS transistor of the second data transmission circuit, and the selection signal S accesses an NMOS transistor of the first data transmission circuit and a PMOS transistor of the second data transmission circuit. When a logic value of the selection signal S is 1, the first data transmission circuit is opened to output a D1 negation signal, and after the D1 negation signal is subjected to negation by the second phase inverter, a D1 signal is output. When the logic value of the selection signal S is 0, the second data transmission circuit is opened to output a D0 negation signal, and after the D0 negation signal is subjected to negation by the second phase inverter, a D0 signal is output. Such selector requires six PMOS transistors and six NMOS transistors in composition, and thus is relatively heavy in electric leakage and large in power consumption loss.

Therefore, it is needed to disclose a novel selector to reduce power consumption loss.

### SUMMARY

In view of the above-mentioned defects of the prior art, the invention aims to provide a low power consumption selector for solving issues of heavy electric leakage and large power consumption loss of a conventional selector in the prior art.

In order to fulfill the above-mentioned objective and other related objectives, the invention provides a low power consumption selector, at least including: a first PMOS tube, a first NMOS tube and a buffer. Gate electrodes of the first PMOS tube and the first NMOS tube are connected with a selection signal in common; drain electrodes of the first PMOS tube and the first NMOS tube are connected, and a node of the drain electrodes is used as an input end of the buffer; and an output end of the buffer is used as an output end of the low power consumption selector.

Preferably, the buffer consists of second and third PMOS tubes and second and third NMOS tubes, wherein gate electrodes of the second PMOS tube and the second NMOS tube are connected to form the input end of the buffer; and drain electrodes of the second PMOS tube and the second NMOS tube are connected with gate electrodes of the third PMOS tube and the third NMOS tube. Drain electrodes of the third PMOS tube and the third NMOS tube are connected to form the output end of the low power consumption selector.

Preferably, source electrodes of the second and third PMOS tubes are connected mutually and access a power supply voltage; and source electrodes of the second and third NMOS tubes are connected mutually and are grounded.

Preferably, base electrodes of the first, second and third PMOS tubes are connected with the power supply voltage; and base electrodes of the first, second and third NMOS tubes are grounded.

Preferably, a source electrode of the first PMOS tube is connected with a first data signal; when a logic value of the selection signal is 0, a signal output by the node used as the output end is the first data signal; and when the logic value of the selection signal is 1, the first PMOS tube is turned off.

Preferably, a source electrode of the first NMOS tube is connected with a second data signal; when the logic value of the selection signal is 1, the signal output by the node used as the output end is the second data signal; and when the logic value of the selection signal is 0, the first NMOS tube is turned off.

Preferably, when a logic signal input by the input end of the buffer is 1, a logic signal output by the output end of the buffer is also 1.

Preferably, when the logic signal input by the input end of the buffer is 0, the logic signal output by the output end of the buffer is also 0.

As the above, the low power consumption selector provided by the invention has the following beneficial effect that: the low power consumption selector provided by the invention can be implemented only by three PMOS transistors and three NMOS transistors, so that power consumption loss of a circuit is reduced to a great degree.

### BRIEF DESCRIPTION OF THE DRAWINGS

FIG. 1 shows a circuit diagram of a conventional selector;

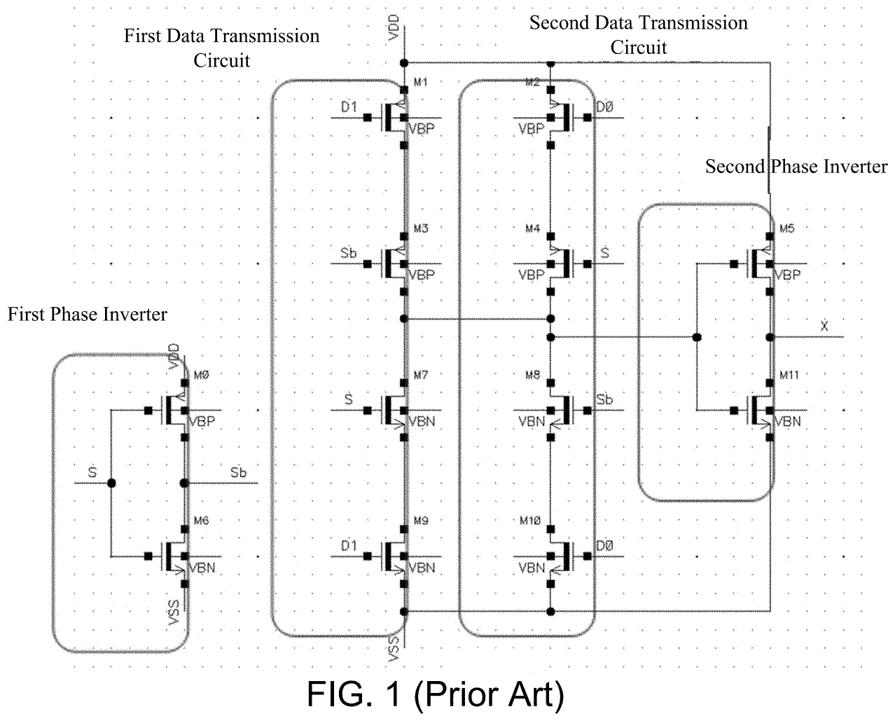

FIG. 2 shows a circuit diagram of a low power consumption selector according to the invention; and

FIG. 3 shows a voltage and current time chart of each signal of the low power consumption selector according to the invention.

### DETAILED DESCRIPTION

Embodiments of the invention will be illustrated below by specific examples, and those skilled in this field can easily know other advantages and effects of the invention by the contents disclosed by this specification. The invention also can be implemented or applied by other different specific embodiments, and various modifications or changes also can be made to each detail in this specification on the basis of different viewpoints and application without departure from the spirit of the invention.

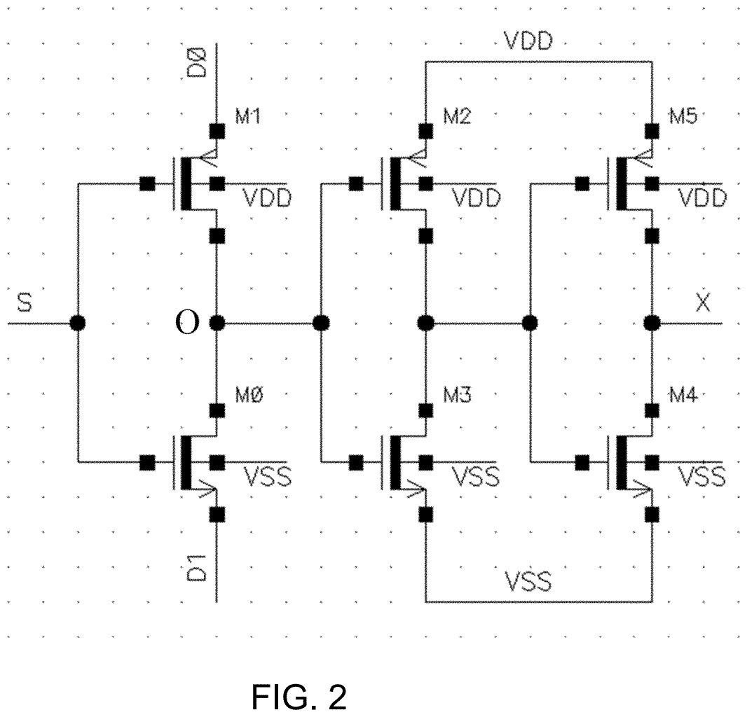

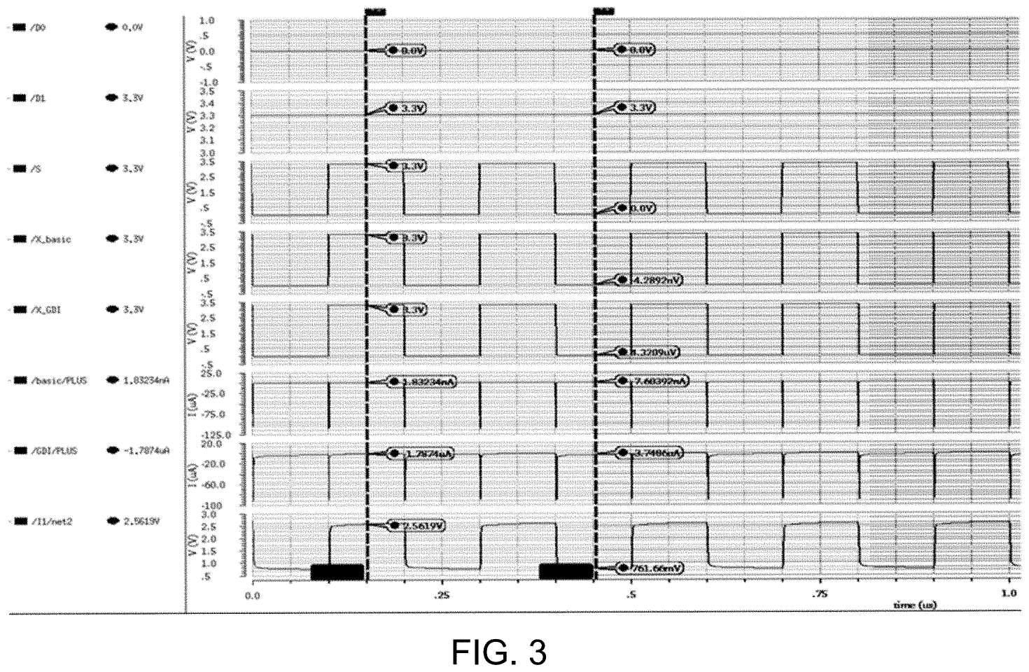

Please refer to FIG. 2 to FIG. 3. It should be illustrated that the diagrams provided in the embodiments merely schematically illustrate the basic conception of the invention, then the diagrams only show related components in the invention, but are not drawn according to the number, shapes and sizes of the components in the actual implementation, the pattern, number and ratio of each component can be randomly changed in the actual implementation, and the pattern of the component layout of the invention also may be more complex.

### Embodiment I

The invention provides a low power consumption selector. With reference to FIG. 2, FIG. 2 shows a circuit diagram of a low power consumption selector according to the invention. The low power consumption selector includes a first PMOS tube M1, a first NMOS tube M1 and a buffer, wherein gate electrodes of the first PMOS tube M1 and the first NMOS tube M1 are connected with a selection signal S in common; drain electrodes of the first PMOS tube M1 and the first NMOS tube M1 are connected, and a node O of the drain electrodes is used as an input end of the buffer; and an output end X of the buffer is used as an output end of the low power consumption selector.

In other words, the selection signal S is connected to the gate electrode of the first PMOS tube M1 and the gate electrode of the first NMOS tube in common, the drain electrode of the first PMOS tube and the drain electrode of the first NMOS tube are connected mutually, and the node O at which the drain electrodes are connected is used as the input end of the buffer. The rightmost end of the circuit is the output end X of the buffer, and the output end X is used as the output end of the low power consumption selector.

When the low power consumption selector provided by the invention normally works, if a source electrode of the first PMOS tube M1 is connected with a first data signal D0 and a logic value of the selection signal S is 0, a signal output by the node O used as the output end is the first data signal D0; and in other words, when the source electrode of the first PMOS tube M1 is connected with the first data signal D0, the gate electrodes of the first PMOS tube M1 and the first NMOS tube M1 are connected with the selection signal S in common and the logic value of the selection signal S is taken as a low level of 0, the node O at which the drain electrodes of the first PMOS tube M1 and the first NMOS tube M0 are connected outputs the first data signal D0.

If the source electrode of the first PMOS tube M1 is connected with the first data signal D0 and the logic value of the selection signal is 1, the first PMOS tube M1 is turned off. Namely, in this stage, the first PMOS tube M1 is turned off without outputting.

In the other case, when the low power consumption selector provided by the invention normally works, the source electrode of the first NMOS tube M1 is connected with a second data signal D1, and when the logic value of the selection signal S is 1, the node O is used as the output end, and the output signal is the second data signal D1; and in other words, when the source electrode of the first NMOS tube M1 is connected with the second data signal D1, the gate electrodes of the first PMOS tube M1 and the first NMOS tube M1 are connected with the selection signal S in common, and the logic value of the selection signal S is taken as a high level of 1, The node O connected with the drain of the first PMOS tube M1 and the first NMOS tube M1 outputs the second data signal D1.

If the source electrode of the first NMOS tube M1 is connected with the second data signal D1 and the logic value of the selection signal is a low level of 0, the first NMOS tube is turned off, i.e., in this stage, the first NMOS tube M1 is turned off without outputting.

As shown in FIG. 2, when a logic signal input by the input end of the buffer in the circuit is 1, a logic signal output by the output end of the buffer is also 1. When the logic signal input by the input end of the buffer is 0, the logic signal output by the output end of the buffer is also 0.

### Embodiment II

The invention further provides another embodiment. This embodiment is different from the above-mentioned embodiment in that: the buffer consists of second and third PMOS tubes and second and third NMOS tubes, wherein gate electrodes of the second PMOS tube and the second NMOS tube are connected to form the input end of the buffer; and drain electrodes of the second PMOS tube and the second NMOS tube are connected with gate electrodes of the third PMOS tube and the third NMOS tube. Drain electrodes of the third PMOS tube and the third NMOS tube are connected to form the output end of the low power consumption selector. In other words, the buffer consists of the second PMOS tube M2, the second NMOS tube M3, the third PMOS tube M5 and the third NMOS tube M4 in FIG. 2, wherein the gate electrode of the second PMOS tube M2 and the gate electrode of the second NMOS tube M3 are connected mutually, and a node at which the gate electrodes are connected is connected with the node O, i.e., a connection end of the gate electrode of the second PMOS tube M2 and the gate electrode of the second NMOS tube M3 is used as the input end of the buffer. As shown in FIG. 2, the drain electrode of the second PMOS tube M2, the drain electrode of the second NMOS tube M3, the gate electrode of the third PMOS tube M5 and the gate electrode of the third NMOS tube M4 are connected with each other mutually; and the output end X of the buffer is the node at which the drain electrode of the third PMOS tube M5 and the drain electrode of the third NMOS tube M4 are connected mutually. The node is also the output end of the low power consumption selector.

In this embodiment, further, source electrodes of the second and third PMOS tubes are connected mutually and access a power supply voltage; and source electrodes of the second and third NMOS tubes are connected mutually and are grounded. Namely, the source electrode of the second PMOS tube M2 and the source electrode of the third PMOS tube M5 are connected mutually, and are connected to the power supply voltage VDD in common; and the source electrode of the second NMOS tube M3 and the source electrode of the third NMOS tube are also connected mutually, and are grounded (connected with a VSS) in common.

In this embodiment, furthermore, as shown in FIG. 2, base electrodes of the first, second and third PMOS tubes are connected with the power supply voltage; and base electrodes of the first, second and third NMOS tubes are grounded. Namely, the base electrodes of the first PMOS tube M1, the second PMOS tube M2 and the third PMOS tube M5 are all respectively connected with the power supply voltage VDD; and meanwhile, the base electrode of the first NMOS tube M0, the base electrode of the second NMOS tube M3 and the base electrode of the third NMOS tube M4 are also respectively grounded (connected with the VSS).

In this embodiment, further, when the low power consumption selector normally works, the source electrode of the first PMOS tube M1 is connected with the first data signal D0, the gate electrodes of the first PMOS tube M1 and the first NMOS tube M1 are connected with the selection signal S in common and the logic value of the selection signal S is taken as a low level of 0, the node O at which the drain electrodes of the first PMOS tube M1 and the first NMOS tube M1 are connected outputs the first data signal D0.

If the source electrode of the first PMOS tube M1 is connected with the first data signal D0, when the logic value of the selection signal is 1 and the first PMOS tube is turned off. Namely, in this stage, the first PMOS tube M1 is turned off without outputting.

When the source electrode of the first NMOS tube M1 is connected with the second data signal D1, the gate electrodes of the first PMOS tube M1 and the first NMOS tube M1 are connected with the selection signal S in common and the logic value of the selection signal S is taken as a high level of 1, the node O at which the drain electrodes of the first PMOS tube M1 and the first NMOS tube M1 are connected outputs the second data signal D1.

If the source electrode of the first NMOS tube M1 is connected with the second data signal D1 and the logic value of the selection signal is a low level of 0, the first NMOS tube is turned off, i.e., in this stage, the first NMOS tube M1 is turned off without outputting.

As shown in FIG. 2, when a logic signal input by the input end of the buffer in the circuit is 1, a logic signal output by the output end of the buffer is also 1. When the logic signal input by the input end of the buffer is 0, the logic signal output by the output end of the buffer is also 0.

The conventional selector carries out integration on a current in five working periods to obtain a result of 378.5 nA, and as shown in FIG. 3, the low power consumption selector provided by the invention carries out integration on a current in five working periods to obtain a result of 84.9 nA. The number of transistors used by the low power consumption selector provided by the invention can be reduced by 50%, and according to the invention, 77% of power consumption of a two-input selector can be reduced.

From the above, the low power consumption selector provided by the invention can be implemented only by three PMOS transistors and three NMOS transistors, so that power consumption loss of the circuit is reduced to a great degree. Therefore, the invention effectively overcomes various defects in the prior art and has high industrial utilization value.

The above-mentioned embodiments merely exemplarily illustrate the principle and effects of the invention, but are not intended to limit the invention. Those skilled in this field can make modifications or changes to the above-mentioned embodiments without departure from the spirit and scope of the invention. Therefore, all equivalent modifications or changes completed by those skilled in this field without departure from the spirit and technical ideas disclosed by the invention should also fall within the claims of the invention.

The invention is expounded above with reference to the specific embodiments, but these embodiments are not intended to limit the invention. Various transformations and improvements made by those skilled in this field without deviating from the principle of the invention should also fall within the protection scope of the invention.

1. A low power consumption selector, comprising:
a first PMOS tube, a first NMOS tube and a buffer;
gate electrodes of the first PMOS tube and the first NMOS tube being connected with a selection signal in common; drain electrodes of the first PMOS tube and the first NMOS tube being connected, and a node being used as an input end of the buffer; wherein a source electrode of the first PMOS tube is connected with a first data signal, and when a logic value of the selection signal is 0, a signal output by the node is the first data signal, wherein a source electrode of the first NMOS tube is connected with a second data signal, and when the logic value of the selection signal is 1, the signal output by the node is the second data signal; and an output end of the buffer being used as an output end of the low power consumption selector.

2. The low power consumption selector according to claim 1, wherein the buffer consists of second and third PMOS tubes and second and third NMOS tubes, wherein gate electrodes of the second PMOS tube and the second NMOS tube are connected to form the input end of the buffer; and drain electrodes of the second PMOS tube and the second NMOS tube are connected with gate electrodes of the third PMOS tube and the third NMOS tube drain electrodes of the third PMOS tube and the third NMOS tube are connected to form the output end of the low power consumption selector.

3. The low power consumption selector according to claim 2, wherein source electrodes of the second and third PMOS tubes are connected mutually and access a power supply voltage; and source electrodes of the second and third NMOS tubes are connected mutually and are grounded.

4. The low power consumption selector according to claim 3, wherein base electrodes of the first, second and third PMOS tubes are connected with the power supply voltage; and base electrodes of the first, second and third NMOS tubes are grounded.

5-8. (canceled)

9. The low power consumption selector according to claim 1, wherein when a logic signal input at the input end of the buffer is 1, a logic signal output by the output end of the buffer is also 1.

10. The low power consumption selector according to claim 1, wherein when a logic signal input at the input end of the buffer is 0, a logic signal output by the output end of the buffer is also 0.
